(19) United States
(12) Patent Application Publication
(10) Pub. No.: US 2024/0162011 A1
(43) Pub. Date: May 16, 2024

(54) ADDITION OF EXTERNAL ULTRAVIOLET LIGHT FOR IMPROVED PLASMA STRIKE CONSISTENCY

(71) Applicant: Applied Materials, Inc., Santa Clara, CA (US)

(72) Inventors: Eric Kihara SHONO, San Mateo, CA (US); Vladimir NAGORNY, Tracy, CA (US); Rene GEORGE, San Carlos, CA (US); Vilen K. NESTOROV, Pleasanton, CA (US); Martin John RIPLEY, San Jose, CA (US); Christopher S. OLSEN, Fremont, CA (US)

(21) Appl. No.: 17/987,679

(22) Filed: Nov. 15, 2022

(51) Int. Cl. H01J 37/32

(52) U.S. Cl. CPC H01J 37/32357; H01J 37/32339; H01J 37/3244

(57) ABSTRACT

Embodiments of the present disclosure relate to methods and apparatuses of processing a substrate. The apparatus includes a process chamber, the process chamber including a chamber body, a substrate support, and a remote plasma source. The substrate support is configured to support a substrate within the processing region. The remote plasma source is coupled to the chamber body through a connector. The remote plasma source includes a body, an inlet, an inductive coil, and one or more UV sources. The body has a first end, a second end, and a tube spanning between the first end and the second end. The inlet is coupled to a gas source configured to introduce one or more gases into the body through the first end of the body. The inductive coil loops around the tube. The one or more UV sources are coupled to the first end of the body.

### BACKGROUND

### Field

Embodiments of the present disclosure generally relate to apparatuses and methods for semiconductor device fabrication, and in particular to apparatuses and methods using ultraviolet light to increase plasma strike consistency.

### Description of the Related Art

The production of silicon integrated circuits has placed difficult demands on fabrication operations to increase the number of devices while decreasing the minimum feature sizes on a chip. As technology nodes drive toward thinner and thinner films, short time recipes are utilized. Some recipes only have 3 second plasma times or less in order to achieve thicknesses well under 20 Å.

Strike consistency for plasma can vary from less than 1 second to more than 2 seconds. This can significantly affect wafer-to-wafer (WtW) performance, especially for very short radio frequency (RF) time recipes. Current approaches to achieve the desired thickness targets with longer recipes, lower temperatures, or changing chemistry typically involve trade-offs in film quality. Consistently short time recipes can avoid these trade-offs.

Therefore, an improved methods and apparatuses for improving strike consistency are needed.

### SUMMARY

The present disclosure generally relates to apparatuses and methods for semiconductor device fabrication, and in particular to apparatuses and methods using ultraviolet light to increase plasma strike consistency.

In one embodiment, apparatus for processing a substrate is disclosed. The apparatus includes a process chamber, the process chamber including a chamber body, a substrate support, and a remote plasma source. The substrate support is configured to support a substrate within the processing region. The remote plasma source is coupled to the chamber body through a connector. The remote plasma source includes a body, an inlet, an inductive coil, and one or more UV sources. The body has a first end, a second end, and a tube spanning between the first end and the second end. The inlet is coupled to a gas source configured to introduce one or more gases into the body through the first end of the body. The inductive coil loops around the tube. The one or more UV sources are coupled to the first end of the body.

In another embodiment, a method of processing a substrate is disclosed. The method includes inletting one or more gases from a gas source through an inlet into a first end of a remote plasma source, generating a plasma in a tube of the remote plasma source using an electric bias and UV light emitted from one or more UV sources, flowing the plasma from the tube into a process chamber, and processing a film of the substrate using the plasma. The process chamber includes a chamber body having a processing region and a substrate support configured to support a substrate within the processing region.

In yet another embodiment, an apparatus for processing a substrate is disclosed. The apparatus includes a process chamber. The process chamber includes a chamber body, a substrate support configured to support a substrate within a processing region, and a remote plasma source coupled to the chamber body through a connector. The remote plasma source includes a body, an inlet, a top plate, a bottom plate, a potting layer, a power source, and one or more UV sources. The body has a first end, a second end, and a tube spanning between the first end and the second end. The inlet is coupled to a gas source configured to introduce one or more gases into the body through the first end of the body. The top plate surrounds a top side of the tube. The bottom plate radially surrounds a bottom side the tube. The potting layer is disposed between the top side of the tube and the top plate, between the bottom side of the tube and the bottom plate, and between adjacent portions of the top plate and the bottom plate. The power source is coupled to the top plate and the bottom plate. The one or more UV sources are coupled to the first end of the body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a cross-sectional schematic side view of a process system, according to embodiments described herein.

FIG. 1B is a cross-sectional schematic top view of the process system of FIG. 1A, according to embodiments described herein.

FIG. 2A is a cross-sectional schematic side view of an alternative process system, according to embodiments described herein.

FIG. 2B is a cross-sectional schematic top view of an alternative process system, according to embodiments described herein.

FIG. 3A is a cross-sectional schematic side view of an alternative process system, according to embodiments described herein.

FIG. 3B is a cross-sectional schematic top view of an alternative process system, according to embodiments described herein.

FIG. 3C is a cross-sectional view of an alternative remote plasma source tube, according to embodiments described herein.

FIG. 4 is a cross-sectional view of an alternative remote plasma source tube

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to apparatuses and methods for semiconductor device fabrication, and in particular to methods of using ultraviolet light to increase plasma strike consistency.

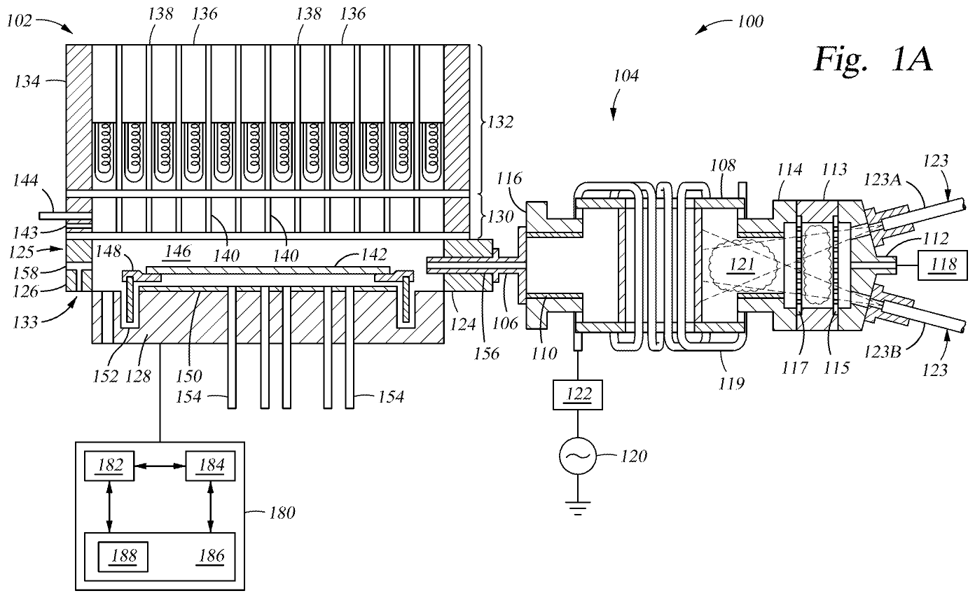

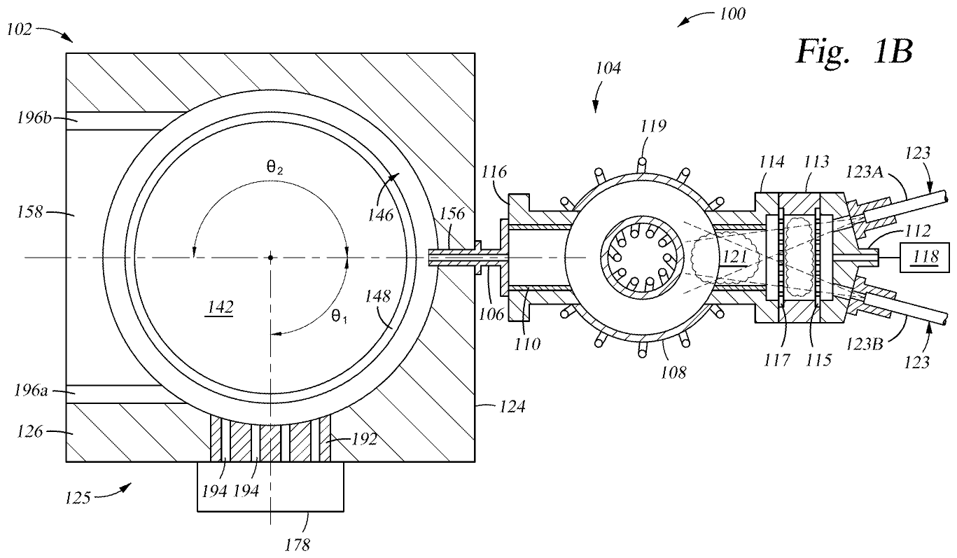

FIG. 1A is a cross-sectional side view of a process system 100. FIG. 1B is a cross-sectional top view of a process system 100. The process system 100 includes a process chamber 102 and a remote plasma source 104. The process chamber 102 may be a rapid thermal processing (RTP) chamber. The remote plasma source 104 may be any suitable remote plasma source, such as microwave coupled plasma source, that can operate at a power, for example, of about 500 W to about 6 kW. In the illustrated embodiment, the remote plasma source 104 includes a toroid that can operate at a power, for example, of about 500 W to about 10 kW. The remote plasma source 104 is coupled to the process chamber 102 to flow plasma formed in the remote plasma source 104 toward the process chamber 102. The remote plasma source 104 is coupled to the process chamber 102 via a connector 106. Species formed in the remote plasma source 104 flow through the connector 106 into the process chamber 102 during processing of a substrate.

The remote plasma source 104 includes a body 108 surrounding a tube 110 in which plasma is generated. The tube 110 may be fabricated from quartz, sapphire, or aluminum. The body 108 includes a first end 114 coupled to an inlet 112, and one or more gas sources 118 may be coupled to the inlet 112 for introducing one or more gases into the remote plasma source 104. In one embodiment, the one or more gas sources 118 include an oxygen containing gas source, and the one or more gases include an oxygen containing gas. In one embodiment, the inlet 112 is connected to the first end 114 of the body 108 via a gas body 113. The gas body 113 includes a first grid 115 and a second grid 117. In one embodiment, the first grid 115 and the second grid 117 may be a showerhead. The first grid 115 and the second grid 117 may include a transparent material such as a quartz or aluminum oxide. The first grid 115 and the second grid 117 include a plurality of holes. In one embodiment, the holes have a diameter of between about 0.5 cm and about 2 cm.

The remote plasma source 104 further includes one or more ultraviolet (UV) sources 123. In the illustrated embodiment, the remote plasma source 104 has a first UV source 123A and a second UV source 123B. The first UV source 123A and second UV source 123B are positioned to emit a UV light through the gas body 113 and into the tube 110. In one embodiment, the first UV source 123A is positioned at an angle of about 0° and about 45° from the inlet 112, such has about 5° and about 25°. The second UV source 123B is positioned at an angle of about 0° and about 45° from the inlet 112, such has about 5° and about 25°. While two UV light sources are illustrated, it is contemplated that more or less than two UV light sources may be utilized. The UV sources 123A, 123B have a power range greater than 500 W, such as between about 500 W and about 2000 W, such as about between about 1000 W and about 5000 W.

In the illustrated embodiment, the tube 110 is a toroidal tube. The toroidal tube 110 has an inductive coil 119 surrounding (e.g., loop around) the toroidal tube 110. The inductive coil 119 initiates the one or more gases into a plasma. The one or more gases are introduced into the toroidal tube 110 at a plasma strike zone 121 within the toroidal tube 110. The strike zone 121 is positioned within the toroidal tube 110 where the UV light emitted from the first UV source 123A and the UV light emitted from the second UV source 123B intersect. In one embodiment, the first UV source 123A and the second UV source 123B are positioned about 1 cm to about 10 cm, such as about 6 cm, from the strike zone 121. The UV sources 123A, 123B is directed directly at the plasma strike zone 121, where the electric fields are strongest, in order to promote the initiation of the gases into the plasma.

The body 108 includes a second end 116 opposite the first end 114, and the second end 116 is coupled to the connector 106. The tube 110 spans between the first end 114 and the second end 116 of the body 108. An optional coupling liner may be disposed within the body 108 at the second end 116. A power source 120 (e.g., an RF power source) may be coupled to the inductive coil 119 of the remote plasma source 104 via a match network 122 to provide power to the remote plasma source 104 to facilitate the forming of the plasma within the toroidal tube 110. The species within the plasma are flowed to the process chamber 102 via the connector 106.

The first UV source 123A and the second UV source 123B further facilitate the forming of the plasma within the toroidal tube 110. For applications in which thin films are manufactured on the scale less than about 20 Å, consistent plasma strike times less than 3 seconds are utilized to achieve wafer-to-wafer (WtW) consistency. The average strike times while using the UV source 123 are less than about 2.1 seconds, such as about 2.07 second or less. In contrast, the average strike time without the UV sources 123A, 123B can be greater than 2.2 seconds. The shorter average strike time of the UV source system allows for greater control of the WtW thickness of the film being deposited in the process chamber 102. Using a remote plasma source with just the inductive coils to generate the plasma leads to a WtW variation of about 3% or greater. By using UV light from the UV sources 123A, 123B, the WtW variation of the deposited film in the process chamber 102 is less than about 3%, such as less than about 2.8%, such as about 2.6%. E.g. the variation of the thickness from any of a plurality of previous substrate to the substrate 142 and from any of a plurality of subsequent substrates to the substrate 142. Not to be bound by theory, it is believed that additional energy provided by the UV sources 123A, 123B assists in the generation of plasma, resulting in the improvements noted above.

The process chamber 102 includes a chamber body 125, a substrate support portion 128, and a window assembly 130. The chamber body 125 includes a first side 124 and a second side 126 opposite the first side 124. In some embodiments, a lamp assembly 132 enclosed by an upper sidewall 134 is positioned over and coupled to the window assembly 130. The lamp assembly 132 may include a plurality of lamps 136 and a plurality of tubes 138, and each lamp 136 may be disposed in a corresponding tube 138. The window assembly 130 may include a plurality of light pipes 140, and each light pipe 140 may be aligned with a corresponding tube 138 so the thermal energy produced by the plurality of lamps 136 can reach a substrate disposed in the process chamber 102. In some embodiments, a vacuum condition can be produced in the plurality of light pipes 140 by applying a vacuum to an exhaust 144 fluidly coupled to the plurality of light pipes 140. The window assembly 130 may have a conduit 143 formed therein for circulating a cooling fluid through the window assembly 130.

A processing region 146 may be defined by the chamber body 125, the substrate support portion 128, and the window assembly 130. A substrate 142 is disposed in the processing region 146 and is supported by a substrate support. In the illustrated embodiment, the substrate support is a support ring 148 above a reflector plate 150. However, other substrate supports are contemplated by this disclosure, i.e., a pedestal. The support ring 148 may be mounted on a rotatable cylinder 152 to facilitate rotating of the substrate 142. The cylinder 152 may be levitated and rotated by a magnetic levitation system (not shown). The reflector plate 150 reflects energy to a backside of the substrate 142 to facilitate uniform heating of the substrate 142 and promote energy efficiency of the process system 100. A plurality of fiber optic probes 154 may be disposed through the substrate support portion 128 and the reflector plate 150 to facilitate monitoring a temperature of the substrate 142.

A liner assembly 156 is disposed in the first side 124 of the chamber body 125 for species to flow from the remote plasma source 104 to the processing region 146 of the process chamber 102. The liner assembly 156 may be fabricated from a material that is oxidation resistant, such as quartz, in order to reduce interaction with process gases, such as oxygen radicals. The liner assembly 156 is designed to reduce flow constriction of radical flowing to the process chamber 102. The process chamber 102 further includes a distributed pumping structure 133 formed in the substrate support portion 128 adjacent to the second side 126 of the chamber body 125 to tune the flow of species from the liner assembly 156 to the pumping ports. The distributed pumping structure 133 is located adjacent to the second side 126 of the chamber body 125.

An opening 158 is disposed through the second side 126 of the chamber body 125. The opening 158 is configured to have a substrate passed therethrough. The opening 158 may be disposed adjacent to a transfer chamber or another process system.

A controller 180 may be coupled to various components of the process system 100, such as the process chamber 102 and/or the remote plasma source 104 to control the operation thereof. The controller 180 generally includes a central processing unit (CPU) 182, a memory 186, and support circuits 184 for the CPU 182. The controller 180 may control the process system 100 directly, or via other computers or controllers (not shown) associated with particular support system components. The controller 180 may be one of any form of general-purpose computer processor that can be used in an industrial setting for controlling various chambers and sub-processors. The memory 186, or computer-readable medium, may be one or more of readily available memory such as random access memory (RAM), read only memory (ROM), floppy disk, hard disk, flash drive, or any other form of digital storage, local or remote. The support circuits 184 are coupled to the CPU 182 for supporting the processor in a conventional manner. The support circuits 184 include cache, power supplies, clock circuits, input/output circuitry and subsystems, and the like. Processing operations may be stored in the memory 186 as a software routine 188 that may be executed or invoked to turn the controller 180 into a specific purpose controller to control the operations of the process system 100. The controller 180 may be configured to perform any methods described herein.

The process system 100 includes both the remote plasma source 104 and a gas injector 192. The liner assembly 156 of the remote plasma source 104 and the gas injector 192 are disposed at different points along the circumference of the processing region 146. Including both of the remote plasma source 104 and the gas injector 192 disposed through the same chamber body 125 and in communication with the same processing region 146 enables both of a high pressure oxidation operation and a low pressure plasma operation to be performed within the same processing region 146.

One or more exhaust passages 196 are disposed adjacent to and/or within the opening 158. The one or more exhaust passages 196 are exhaust outlets and are configured to exhaust gas and/or plasma from the processing region 146. The one or more exhaust passages 196 are coupled to one or more exhaust pumps (not shown) to remove the exhaust gases and/or plasmas within the processing region 146. The one or more exhaust passages 196 include at least a first exhaust passage 196a and a second exhaust passage 196b. The first exhaust passage 196a is disposed on a first side of the opening 158, while the second exhaust passage 196b is disposed on the opposite side of the opening 158. Utilizing the first and second exhaust passages 196a, 196b on opposite sides of the opening 158 enables more even evacuation of process gases and plasmas during processing.

The gas injector 192 is disposed through a wall of the chamber body 125. The gas injector 192 includes a plurality of gas passages 194 therethrough and in fluid communication with the processing region 146. The gas injector 192 is configured to inject process gases into the processing region 146 and across a top surface of the substrate 142. The gas injector 192 and each of the gas passages 194 disposed therein are coupled to a process gas source 178. The process gas source 178 is configured to supply one or more oxidants. The one or more oxidants include one or a mixture of hydrogen (H₂), oxygen (O₂), ozone (O₃), nitrous oxide (N₂O), water/water vapor (H₂O), hydrogen peroxide (H₂O₂), or hydroxide (OH⁻).

The center of the gas injector 192 may be disposed at a first angle θ₁ with respect to the center of the liner assembly 156 of the remote plasma source 104. The first angle θ₁ is about 45 degrees to about 135 degrees, such as about 60 degrees to about 120 degrees, such as about 75 degrees to about 105 degrees. In some embodiments, the first angle θ₁ is about 90 degrees, such that the gas injector 192 and the liner assembly 156 of the remote plasma source 104 are perpendicular to one another along the circumference of the processing region 146. Positioning each of the gas injector 192 and the liner assembly 156 at separate circumferential positions of the processing region enables both components to be utilized independently within the process system 100.

The center of the liner assembly 156 of the remote plasma source 104 is disposed at a second angle θ₂ with respect to a center of the opening 158 through which the substrate 142 is configured to pass into and out of the processing region 146. The second angle θ₂ is about 150 degrees to about 210 degrees, such as about 175 degrees to about 195 degrees, such as about 190 degrees. In some embodiments, the liner assembly 156 and the opening 158 are aligned along a similar axis. Aligning the liner assembly 156 and the opening 158 enables plasma to be flowed evenly across the substrate 142 and evacuated through one or more exhaust passages 196a, 196b on either side of the opening 158. Positioning each of the gas injector 192 and the opening 158 at angles to one another enables a spiral gas flow across the surface of the substrate 142. The spiral gas flow has been shown to enable more even oxide formation.

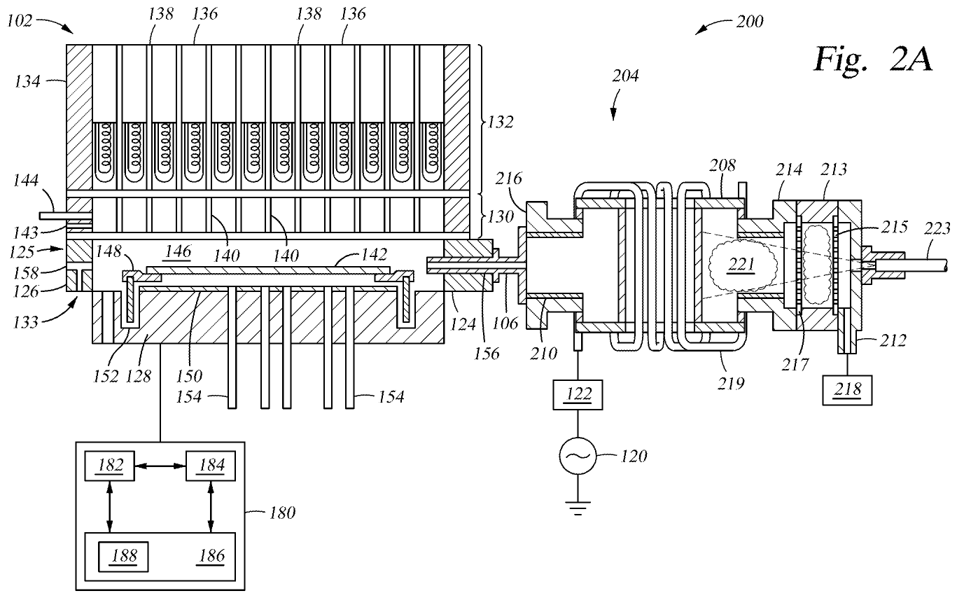

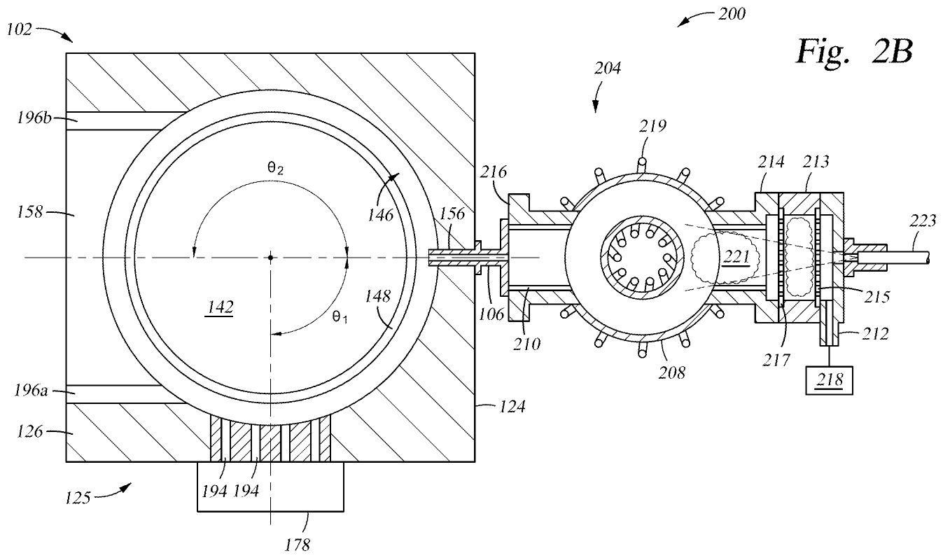

FIG. 2A is a cross-sectional side view of an alternative process system 200. FIG. 2B is a cross-sectional top view of an alternative process system 200. The alternative process system 200 includes a process chamber 102 and a remote plasma source 204. The remote plasma source 204 may be used in place of the remote plasma source 104. The process chamber 102 may be a rapid thermal processing (RTP) chamber. The remote plasma source 204 may be any suitable remote plasma source, such as microwave coupled plasma source, that can operate at a power, for example, of about 500 W to about 6 kW. In the illustrated embodiment, the remote plasma source 204 is a toroid that can operate at a power, for example, of about 500 W to about 10 kW. The remote plasma source 204 is coupled to the process chamber 102 to flow plasma formed in the remote plasma source 204 toward the process chamber 102. The remote plasma source 204 is coupled to the process chamber 102 via a connector 106. Species formed within the remote plasma source 204 flow through the connector 106 into the process chamber 102 during processing of a substrate.

The remote plasma source 204 includes a body 208 surrounding a tube 210 in which plasma is generated. The tube 210 may be fabricated from quartz or sapphire. The body 208 includes a first end 214 coupled to an inlet 212, and one or more gas sources 218 may be coupled to the inlet 212 for introducing one or more gases into the remote plasma source 204. In one embodiment, the one or more gas sources 218 include an oxygen containing gas source, and the one or more gases include an oxygen containing gas. In one embodiment, the inlet 212 is connected to the first end 214 of the body 208 via a gas body 213. The gas body 213 includes a first grid 215 and a second grid 217. In one embodiment, the first grid 215 and the second grid 217 may be a showerhead. The first grid 215 and the second grid 217 may include a quartz material or an aluminum material. The first grid 215 and the second grid 217 include a plurality of holes. In one embodiment, the holes have a diameter of between about 0.5 cm and about 2 cm.

The remote plasma source 204 further includes one or more UV sources 223. In the illustrated embodiment, the remote plasma source 204 has a single UV source. The UV source 123 is positioned to emit a UV light through the gas body 213 and into the tube 210. In one embodiment, the UV source 123 is positioned perpendicular to the inlet 212. While one UV light source is illustrated, it is contemplated that more than one UV light source perpendicular to the inlet may be utilized. The UV sources 123 have a power range greater than 500 W, such as between about 500 W and about 2000 W, such as about between about 1000 W and about 5000 W.

In the illustrated embodiment, the tube 210 is a toroidal tube. The toroidal tube 210 has an inductive coil 219 radially surrounding the toroidal tube 210. The inductive coil 219 initiates the one or more gases into a plasma. The one or more gases introduced into the toroidal tube 210 at a plasma strike zone 221 within the toroidal tube 210. In one embodiment, the UV source 223 is positioned about 1 cm to about 10 cm, such as about 6 cm from the strike zone 221. The UV source 223 is directed directly at the plasma strike zone 221, where the electric fields are strongest, in order to promote the initiation of the gases into the plasma.

The UV source 223 further facilitates the forming of the plasma within the toroidal tube. For applications in which thin films are deposited onto a substrate 142 on the scale less than about 20 Å, consistent plasma strike times less than 3 seconds are utilized to achieve wafer-to-wafer (WtW) consistency. The WtW consistency is the variation of the thickness from any of a plurality of previous substrates to the substrate 142 and from any of a plurality of subsequent substrates to the substrate 142. The average strike times while using the UV source 223 are less than about 2.1 second such as about 2.07 second or less. In contrast, the average strike time without the UV source 223 can be greater than 2.2 seconds. The shorter average strike time of the UV source system allows for greater control of the WtW thickness of the film being deposited in the process chamber 202. Using a remote plasma source with just the inductive coils to generate the plasma leads to a WtW variation of about 3% or greater. By using UV light from the UV source 223, the WtW variation of the deposited film in the process chamber 102 is less than about 3%, such as less than about 2.8%, such as about 2.6%. E.g. the variation of the thickness from any of a plurality of previous substrate to the substrate 142 and from any of a plurality of subsequent substrates to the substrate 142. Not to be bound by theory, it is believed that additional energy provided by the UV sources 123A, 123B assists in the generation of plasma, resulting in the improvements noted above.

The body 208 includes a second end 216 opposite the first end 214, and the second end 216 is coupled to the connector 106. An optional coupling liner may be disposed within the body 208 at the second end 216. A power source 120 (e.g., an RF power source) may be coupled to the inductive coil 219 of the remote plasma source 204 via a match network 122 to provide power to the remote plasma source 204 to facilitate the forming of the plasma within the toroidal tube 210. The species in the plasma are flowed to the process chamber 102 via the connector 106.

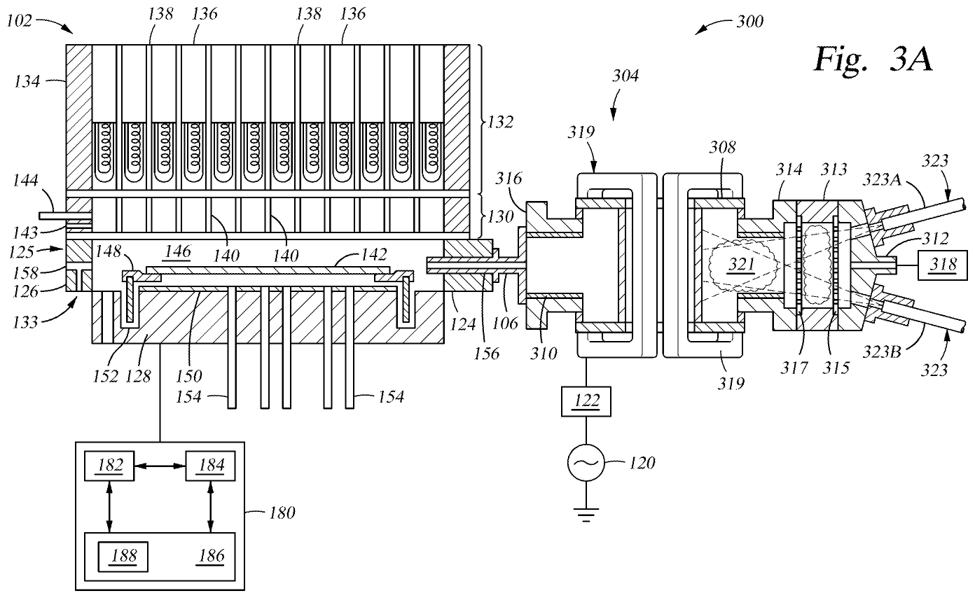

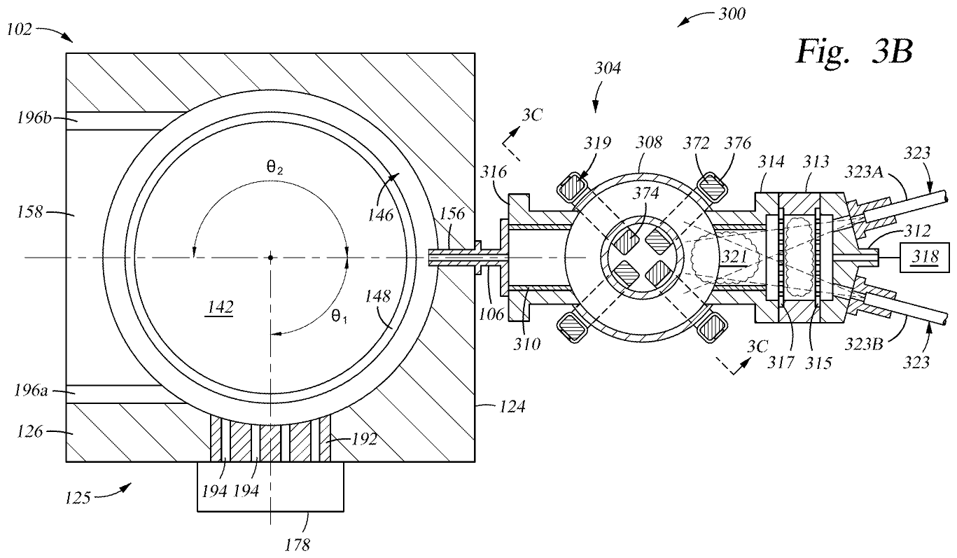

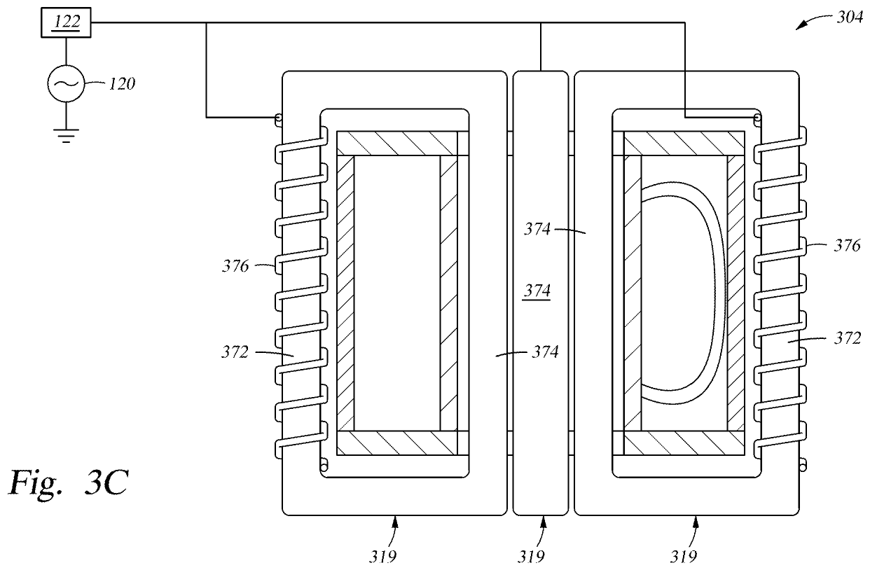

FIG. 3A is a cross-sectional side view of an alternative process system 300. FIG. 3B is a cross-sectional top view of an alternative process system 300. FIG. 3C is a cross-sectional view of an alternative remote plasma source tube 304. The alternative process system 300 includes a process chamber 102 and a remote plasma source 304. The process chamber 102 may be a rapid thermal processing (RTP) chamber. The remote plasma source 304 may be any suitable remote plasma source, such as microwave coupled plasma source, that can operate at a power, for example, of about 500 W to about 6 kW. In the illustrated embodiment, the remote plasma source 304 includes a toroid that can operate at a power, for example, of about 500 W to about 10 kW. The remote plasma source 304 is coupled to the process chamber 102 to flow plasma formed in the remote plasma source 304 toward the process chamber 102. The remote plasma source 304 is coupled to the process chamber 102 via a connector 106. Species formed in the remote plasma source 304 flow through the connector 106 into the process chamber 102 during processing of a substrate.

The remote plasma source 304 includes a body 308 surrounding a tube 310 in which plasma is generated. The tube 310 may be fabricated from quartz, sapphire, or aluminum. The body 308 includes a first end 314 coupled to an inlet 312, and one or more gas sources 318 may be coupled to the inlet 312 for introducing one or more gases into the remote plasma source 304. In one embodiment, the one or more gas sources 318 include an oxygen containing gas source, and the one or more gases include an oxygen containing gas. In one embodiment, the inlet 312 is connected to the first end 314 of the body 308 via a gas body 313. The gas body 313 includes a first grid 315 and a second grid 317. In one embodiment, the first grid 315 and the second grid 317 may be a showerhead. The first grid 315 and the second grid 317 may include a transparent material such as a quartz or aluminum oxide. The first grid 315 and the second grid 317 include a plurality of holes. In one embodiment, the holes have a diameter of between about 0.5 cm and about 2 cm.

The remote plasma source 304 further includes one or more ultraviolet (UV) sources 323. In the illustrated embodiment, the remote plasma source 304 has a first UV source 323A and a second UV source 323B. The first UV source 323A and second UV source 323B are positioned to emit a UV light through the gas body 313 and into the tube 310. In one embodiment, the first UV source 123A is positioned at an angle of about 0° and about 45° from the inlet 112, such has about 5° and about 25°. The second UV source 323B is positioned at an angle of about 0° and about 45° from the inlet 312, such has about 5° and about 25°. While two UV light sources are illustrated, it is contemplated that more or less than two UV light sources may be utilized. In another embodiment, the UV source 323 is positioned perpendicular to the inlet 312. It is contemplated that more than one UV light source perpendicular to the inlet may be utilized. The UV sources 323A, 323B have a power range greater than 500 W, such as between about 500 W and about 2000 W, such as about between about 1000 W and about 5000 W.

In the illustrated embodiment, the tube 310 is a toroidal tube. The toroidal tube 310 has a plurality of metal cores 319 surrounding (e.g., loop around) the toroidal tube 310. The metal cores 319 have an opening 370 through which the tube 310 is disposed. The metal cores 319 further include an outer wall 372 and an inner wall 374. A conductive coil 376 is wrapped around (i.e., surrounds) the outer wall 371 of the metal core 319. The metal cores 319 initiate the one or more gases into a plasma. The one or more gases are introduced into the toroidal tube 310 at a plasma strike zone 321 within the toroidal tube 310. The strike zone 321 is positioned within the toroidal tube 310 where the UV light emitted from the first UV source 323A and the UV light emitted from the second UV source 323B intersect. In one embodiment, the first UV source 323A and the second UV source 323B are positioned about 1 cm to about 10 cm, such as about 6 cm, from the strike zone 321. The UV sources 323A, 323B is directed directly at the plasma strike zone 321, where the electric fields are strongest, in order to promote the initiation of the gases into the plasma.

The body 308 includes a second end 316 opposite the first end 314, and the second end 316 is coupled to the connector 106. The tube 310 spans between the first end 314 and the second end 316 of the body 308. An optional coupling liner may be disposed within the body 308 at the second end 316. A power source 120 (e.g., an RF power source) may be coupled to the conductive coil 376 wrapped around the metal core 319 of the remote plasma source 304 via a match network 122 to provide power to the remote plasma source 304 to facilitate the forming of the plasma within the toroidal tube 310. The conductive coil 376 wrapped around the outer wall 372 of the metal core 319 creates a magnetic flux within the metal core 319, which in turn creates an electric field around the inner wall 374 of the metal core 319. This electric field facilitates the formation of the plasma within the tube 310. The species within the plasma are flowed to the process chamber 102 via the connector 106.

The first UV source 323A and the second UV source 323B further facilitate the forming of the plasma within the toroidal tube 310. For applications in which thin films are manufactured on the scale less than about 20 Å, consistent plasma strike times less than 3 seconds are utilized to achieve wafer-to-wafer (WtW) consistency. The average strike times while using the UV source 323 are less than about 2.1 seconds, such as about 2.07 second or less. In contrast, the average strike time without the UV sources 323A, 323B can be greater than 2.2 seconds. The shorter average strike time of the UV source system allows for greater control of the WtW thickness of the film being deposited in the process chamber 102. Using a remote plasma source with just the inductive coils to generate the plasma leads to a WtW variation of about 3% or greater. By using UV light from the UV sources 323A, 323B, the WtW variation of the deposited film in the process chamber 102 is less than about 3%, such as less than about 2.8%, such as about 2.6%. E.g. the variation of the thickness from any of a plurality of previous substrate to the substrate 142 and from any of a plurality of subsequent substrates to the substrate 142. Not to be bound by theory, it is believed that additional energy provided by the UV sources 323A, 323B assists in the generation of plasma, resulting in the improvements noted above.

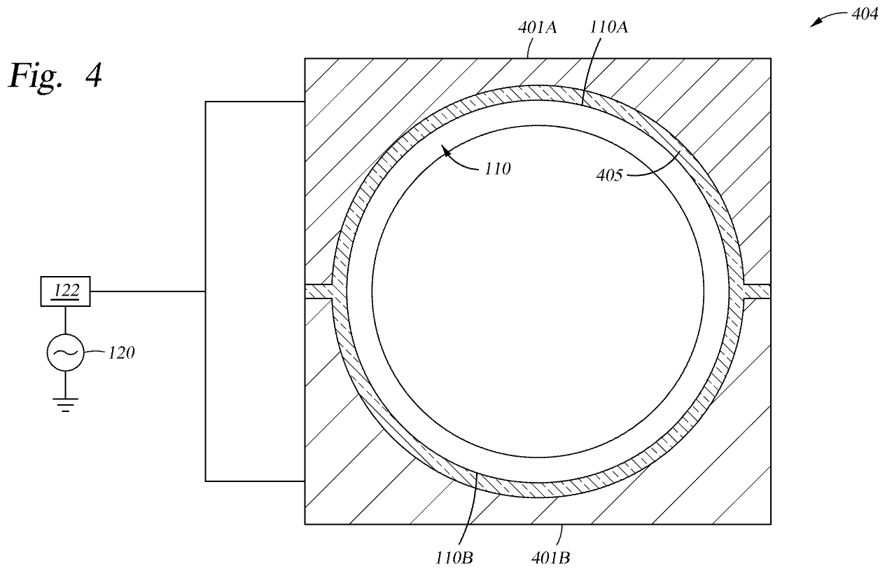

FIG. 4 is a cross-sectional view of an alternative remote plasma source tube 404. The alternative remote plasma source tube 404 includes the tube 110, a top plate 401A, a bottom plate 401B, and a potting layer 405. In one embodiment, the tube 110 is a toroidal tube 110. The toroidal tube 110 is radially surrounded on a top side 110A by the top plate 401A and radially surrounded on the bottom side 110B by the bottom plate 401B. The potting layer 405 is disposed between the top side 110A of the tube 110 and the top plate 401A, between the bottom side 110B of the tube 110 and the bottom plate 401B, and between the adjacent portions of the top plate 401A and the bottom plate 401B. The potting layer 405 includes an insulative material. A power source 120 (e.g., an RF power source) may be coupled to the top plate 401A and the bottom plate 401B of the remote plasma source tube 404 via a match network 122 to provide power (e.g., an electrical bias) to the remote plasma source tube 404. The power supplied to the top plate 401A and the bottom plate 301B is between about 500 W to about 10 kW. The potting layer 405 provides insulation between the top plate 401A and the bottom plate 401B in order to create a bias between the top plate 401A and the bottom plate 401B. The bias between the top plate 401A and the bottom plate 401B facilitates the forming of the plasma within the toroidal tube 110. When the bias is applied, the top plate 401A and bottom plate 401B act as electrodes. The species in the plasma are flowed to the process chamber 102 via the connector 106.

The alternative remote plasma source tube 404 results in a larger surface area for a spark voltage during plasma strike, relative to other embodiments. The larger surface area facilitates an increased likelihood of plasma striking. In addition, the alternative remote plasma source tube 404 creates a higher electric field relative to other embodiments. A higher electric field drives electrons faster, promoting plasma striking. In one embodiment, the top plate 401A and bottom plate 401B are water cooled in order to remove unwanted heat from the plasma.

While the foregoing is directed to embodiments of the present disclosure, other and further embodiments of the disclosure may be devised without departing from the basic scope thereof, and the scope thereof is determined by the claims that follow.

What is claimed is:

1. An apparatus, comprising:
a process chamber, the process chamber comprising:
a chamber body;
a substrate support configured to support a substrate within a processing region;
a remote plasma source coupled to the chamber body through a connector, the remote plasma source comprising:
a body, the body having a first end, a second end, and a tube spanning between the first end and the second end;
an inlet coupled to a gas source configured to introduce one or more gases into the body through the first end of the body;
an inductive coil looped around the tube; and
one or more UV sources coupled to the first end of the body.

2. The apparatus of claim 1, wherein a UV source of the one or more UV sources is angled perpendicular to the inlet.

3. The apparatus of claim 1, wherein a UV source of the one or more UV sources is positioned at an angle of 5° and 25° from the inlet.

4. The apparatus of claim 3, wherein a second UV source of the one or more UV sources is positioned at an angle of 5° and 25° from the inlet.

5. The apparatus of claim 1, wherein the one or more UV sources is positioned 1 cm to 10 cm from a strike zone of the remote plasma source.

6. The apparatus of claim 1, wherein the inductive coil looped around the tube includes a plurality of metal cores and a conductive coil, wherein the metal cores have an opening through which the tube is disposed, an outer wall and an inner wall, and wherein the conductive coil is wrapped surrounds the outer wall of the metal cores.

7. The apparatus of claim 6, wherein the one or more UV sources have a power range greater than 500 W.

8. A method of processing a substrate, the method comprising:
inletting one or more gases from a gas source through an inlet into a first end of a remote plasma source;
generating a plasma in a tube of the remote plasma source using an electric bias and UV light emitted from one or more UV sources;
flowing the plasma from the tube into a process chamber, the process chamber comprising a chamber body having a processing region and a substrate support configured to support a substrate within the processing region; and
processing a film of the substrate using the plasma.

9. The method of claim 8, wherein an average strike time of the gases into a plasma is less than 2.07 seconds.

10. The method of claim 8, wherein a thickness of the film on the substrate varies, on average, less than 2.6% from any of a plurality of previous substrate and less than 2.6% from any of a plurality of subsequent substrates.

11. The method of claim 8, wherein the electric bias is supplied using an inductive coil.

12. The method of claim 8, wherein the electric bias is supplied to a top plate surrounding a top side of the tube and a bottom plate radially surrounding a bottom side the tube, wherein a potting layer is disposed between the top side of the tube and the top plate, between the bottom side of the tube and the bottom plate, and between adjacent portions of the top plate and the bottom plate.

13. The method of claim 8, wherein a UV source of the one or more UV sources is angled perpendicular to the inlet.

14. The method of claim 8, wherein a UV source of the one or more UV sources is positioned at an angle of 5° and 25° from the inlet.

15. The method of claim 14, wherein a second UV source is positioned at an angle of 5° and 25° from the inlet.

16. The method of claim 15, wherein the one or more UV sources are positioned 1 cm to 10 cm from a strike zone.

17. An apparatus, comprising:
a process chamber, the process chamber comprising:
a chamber body;
a substrate support configured to support a substrate within a processing region;
a remote plasma source coupled to the chamber body through a connector; the remote plasma source comprising:
a body, the body having a first end, a second end, and a tube spanning between the first end and the second end;
an inlet coupled to a gas source configured to introduce one or more gases into the body through the first end of the body;
a top plate surrounding a top side of the tube;
a bottom plate radially surrounding a bottom side the tube;
a potting layer is disposed between the top side of the tube and the top plate, between the bottom side of the tube and the bottom plate, and between adjacent portions of the top plate and the bottom plate;
a power source coupled to the top plate and the bottom plate; and
one or more UV sources coupled to the first end of the body.

18. The apparatus of claim 17, wherein the potting layer comprises an insulative material.

19. The apparatus of claim 18, wherein the body comprises a gas body, the gas body having one or more grids.

20. The apparatus of claim 18, wherein the one or more UV sources is positioned 1 cm to 10 cm from a strike zone.
